(19) United States
(12) Patent Application Publication
(10) Pub. No.: US 2012/0194990 A1
(43) Pub. Date: Aug. 2, 2012

(54) Semiconductor Arrangements

(76) Inventor: Martin Kuster, Walchwil (CH)

(21) Appl. No.: 13/346,168

(22) Filed: Jan. 9, 2012

Related U.S. Application Data
(60) Provisional application No. 61/438,123, filed on Jan. 31, 2011.

(51) Int. Cl. G06F 1/16; H05K 7/06

(52) U.S. Cl. 361/679.31; 361/760; 361/774

(57) ABSTRACT

Electronic component packages comprising a first substrate and a second substrate, each bearing electronic components. The substrates are interconnected using a flexible film cable and then folded relative to each other to form a stacked structure. The length and/or width of the package so formed allows for provision of additional substrate space to accommodate additional electronic components, without unnecessarily requiring undesired additional substrate length or width dimensions that might impair desired form factor considerations.

This invention relates generally to electronic component packages comprising substrates to which are mounted electronic components.

### BACKGROUND

Continuing advances in technology drive the need for new and additional electronic components and other devices to provide desired functionality. For example, advances in mass storage technology and communications interfaces create the opportunity for external memory devices such as flash memory devices or chip on board memory devices to provide additional memory and/or additional physical and electronic interfaces to interoperate with host devices. In such events, substrates such as printed circuit board can be conventionally expanded in length and/or width to accommodate such new and/or additional components. However, it can be the case that commercial considerations or user expectations limit such expansion. There is accordingly a consequent need for, among other things, structures that allow additional substrate space in order to accommodate new and/or additional electronic components without unduly increasing dimensions of the substrate either in length or width in a manner that could, among other things, derogate from desired form factor considerations, commercial considerations, or user expectations.

### SUMMARY

Accordingly, there is provided an electronic component package, comprising a first substrate comprising a first substrate first side, a first substrate second side, a first substrate length dimension and a first substrate width dimension; a plurality of first substrate electronic components mounted on the first substrate first side, at least some of the first substrate electronic components electrically connected to each other; a second substrate comprising a second substrate first side, a second substrate second side, a second substrate length dimension and a second substrate width dimension; a plurality of second substrate electronic components mounted on the second substrate first side, at least some of the second substrate electronic components electrically connected to each other; a flexible film cable electrically connecting at least some of the first substrate electronic components to at least some of the second substrate electronic components; the first substrate and the second substrates disposed in a stacked relationship where the first substrate first side is disposed adjacent to the second substrate first side.

In some embodiments, the package comprises a package length dimension that does not exceed the greater of the first substrate length dimension and the second substrate length dimension.

In some embodiments, the package comprises a width dimension that does not exceed the greater of the first substrate width dimension and the second substrate width dimension.

In some embodiments, the first substrate and the second substrate are bound to each other with polymeric material.

In some embodiments, the first substrate second side and the second substrate second side comprise conductive pathways that connect electronic components to each other.

In some embodiments, the first substrate comprises a plurality of through holes, the through holes configured to permit electrical connection of electronic components on the first substrate first side to electronic components on the first substrate second side.

In some embodiments, the second substrate comprises a plurality of through holes, the through holes configured to permit electrical connection of electronic components on the second substrate first side to electronic components on the second substrate second side.

In some embodiments, at least one of the first substrate and the second substrate includes a plurality of contacts configured to permit connection of at least some electronic components mounted on at least one of the first substrate and the second substrate to an external device. In some of such embodiments the electronic components comprise a mass memory device, a controller and at least one optical device, and the contacts are configured to comply with a universal serial bus standard and surrounded by a plug housing configured to comply with the universal serial bus standard. In some of such embodiments, at least one of the first substrate and the second substrate includes a first plurality of contacts configured to comply with a first interconnection standard and a second plurality of contacts configured to comply with a second interconnection standard.

In some embodiments, at least some of the electronic components are surface mounted to at least one of the first substrate and the second substrate.

In some embodiments, the package further comprises a plurality of electronic components mounted to the first substrate second side.

In some embodiments, the package further comprises a plurality of electronic components mounted to the second substrate second side.

In some embodiments, at least one of the first substrate and the second substrate comprises a plurality of conductive layers, each conductive layer separated from another conductive layer by an insulative layer, and a plurality of vias in at least one insulative layer, the vias permitting connection of conductive pathways in a conductive layer to conductive pathways in another conductive layer.

In some embodiments, the flexible film cable electrically connects at least some of the first substrate electronic components to at least some of the second substrate electronic components using cable connectors.

In some embodiments, the flexible film cable electrically connects at least some of the first substrate electronic components to at least some of the second substrate electronic components using solder connections.

There is also provided an electronic component package, comprising: a first substrate comprising a first substrate first side, a first substrate second side, a first substrate length dimension and a first substrate width dimension; a plurality of first substrate electronic components mounted on the first substrate first side, at least some of the first substrate electronic components electrically connected to each other; a second substrate comprising a second substrate first side, a second substrate second side, a second substrate length dimension and a second substrate width dimension; a plurality of second substrate electronic components mounted on the second substrate first side, at least some of the second substrate electronic components electrically connected to each other; electronic components on at least one of the first substrate and the second substrate comprising a controller; electronic components on at least one of the first substrate and the second substrate comprising a mass memory device; at least one of the first substrate and the second substrate comprising a first plurality of contacts configured to comply with a first interconnection standard; a housing connected to at least one of the substrates, the housing configured to surround the first plurality of contacts, and to comply with the first interconnection standard; a flexible film cable electrically connecting at least some of the first substrate electronic components to at least some of the second substrate electronic components; the first substrate and the second substrate disposed in a stacked relationship wherein the first substrate first side is disposed adjacent to the second substrate first side; wherein the package comprises a package length dimension that does not exceed the greater of the first substrate length dimension and the second substrate length dimension and wherein the package comprises a width dimension that does not exceed the greater of the first substrate width dimension and the second substrate width dimension.

In some embodiments, the first plurality of contacts is configured to comply with a universal serial bus standard.

In some embodiments, the second substrate further comprises a second plurality of contacts configured to comply with a second interconnection standard and a housing configured to surround the first plurality of contacts and the second plurality of contacts, and to comply with the first interconnection standard and the second interconnection standard. In some such embodiments, the second plurality of contacts and the housing are configured to comply with a serial advanced technology advancement standard.

In some embodiments, the package includes an optical device.

There is also provided an electronic component package, comprising: a first substrate comprising a first substrate first side, a first substrate second side, a first substrate length dimension and a first substrate width dimension; a plurality of first substrate electronic components mounted on the first substrate first side, at least some of the first substrate electronic components electrically connected to each other; a second substrate comprising a second substrate first side, a second substrate second side, a second substrate length dimension and a second substrate width dimension; a plurality of second substrate electronic components mounted on the second substrate first side, at least some of the second substrate electronic components electrically connected to each other; electronic components on at least one of the first substrate and the second substrate comprising a controller; electronic components on at least one of the first substrate and the second substrate comprising a mass memory device; at least one of the first substrate and the second substrate comprising a first plurality of contacts configured to comply with a universal serial bus standard and a second plurality of contacts configured to comply with a second interconnection standard; a housing connected to at least one of the substrates, the housing configured to surround the first plurality of contacts and the second plurality of contacts, and to comply with the universal serial bus standard and the second interconnection standard; a flexible film cable electrically connecting at least some of the first substrate electronic components to at least some of the second substrate electronic components; the first substrate and the second substrate disposed in a stacked relationship wherein the first substrate first side is disposed adjacent to the second substrate first side; wherein the package comprises a package length dimension that does not exceed the greater of the first substrate length dimension and the second substrate length dimension and wherein the package comprises a width dimension that does not exceed the greater of the first substrate width dimension and the second substrate width dimension.

### BRIEF DESCRIPTION OF THE DRAWINGS

FIGS. 1A and 1B show schematic views of an electronic component package according to a first embodiment of the invention.

FIGS. 2A and 2B show schematic views of an electronic component package according to a second embodiment of the invention.

FIG. 3 shows an electronic component package according to a third embodiment of the invention.

FIG. 4 shows the package of FIG. 3 with additional housing elements.

FIGS. 5A and 5B show an electronic component package substrate according to another embodiment of the invention.

FIG. 6 shows an end view of an electronic component package substrate according to another embodiment of the invention.

### DETAILED DESCRIPTION

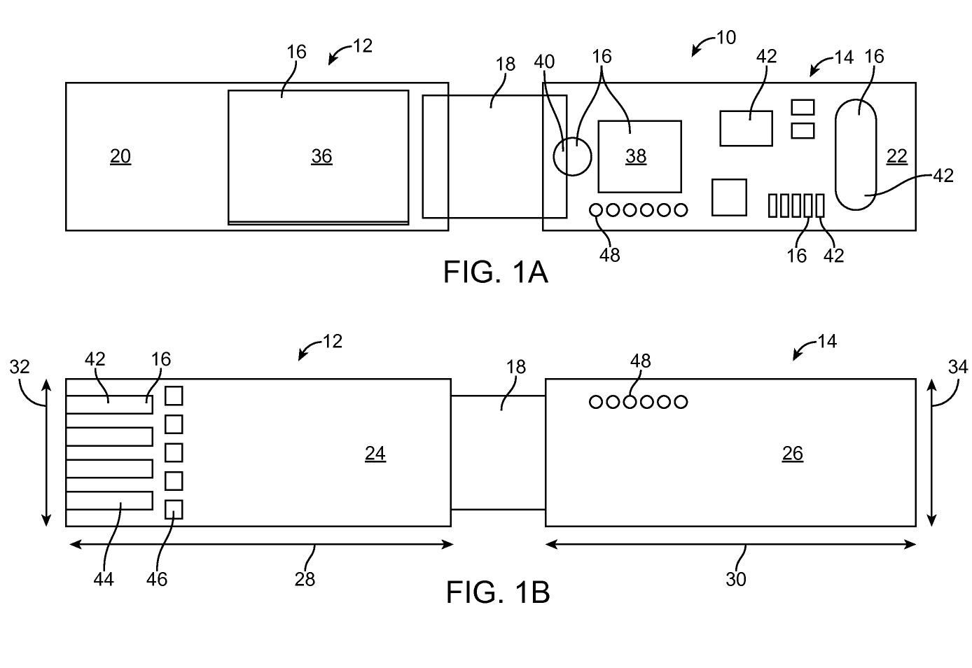

FIGS. 1A and 1B show an electronic component package 10 according to an embodiment of the invention. Package 10 generally includes a first substrate 12 and a second substrate 14. On each substrate is mounted or affixed one or more electronic components 16. At least some of the electronic components 16 mounted on the first substrate 12 may be connected electrically to at least some components 16 mounted on the second substrate 14 by a flexible film cable 18. First substrate 12 includes a first substrate first side 20 as shown in FIG. 1A, whereas second substrate 14 includes a second substrate first side 22 as also shown in FIG. 1A. As shown in FIG. 1B, first substrate 12 also includes a first substrate second side 24, whereas second substrate 12 includes a second substrate second side 26. First substrate 12 also features a first substrate length dimension 28 and a first substrate width dimension 32, while second substrate 14 features a second substrate length dimension 30 and a second substrate width dimension 34. In the embodiment shown in FIGS. 1A and 1B, electronic components 16 include a mass memory device 36, a controller 38, and optical device 40, and other electronic components 42. Additionally, in this embodiment, on first substrate second side 24 is mounted a first plurality of contacts 44 that comply with a first interconnection standard, as well as a second plurality of contacts 46 that comply with a second interconnection standard.

As used herein, “substrate” means a laminated or nonlaminated structure that can be used to support mechanically, and as the case may be to connect electrically, electronic components using electrically conductive pathways such as conductive signal traces etched onto or into, or otherwise formed on or in, dielectric or nonconductive portions of the substrate. An example is a printed circuit board that includes an insulated portion with signal traces formed thereon. Substrates may contain multiple layers of insulated material that separate layers of conductive pathways; in such structures, pathways of different conductive layers can be connected to each other using vias or other inter-layer connections. Substrates may include pads for surface mounting electronic components, and/or they may contain through-holes or vias for allowing electrical connection between components or pathways on one side of the substrate to components or pathways on the other side of the substrate. Insulating layers may be dielectric material of any conventional composition. Traces or other pathways may be etched, patterned or otherwise formed on or in the substrate according to any number of conventional methods. In the embodiment shown in FIGS. 1A and 1B, first substrate first side 20 and second substrate first side 22 primarily accommodate electronic components 16, whereas first substrate second side 24 and second substrate second side 26 accommodate traces or other pathways that interconnect at least some of electronic components 16. Substrates 12 and/or 14 may if desired take the form of thin semiconductor substrates to reduce the ultimate width of package 10 or for other purposes.

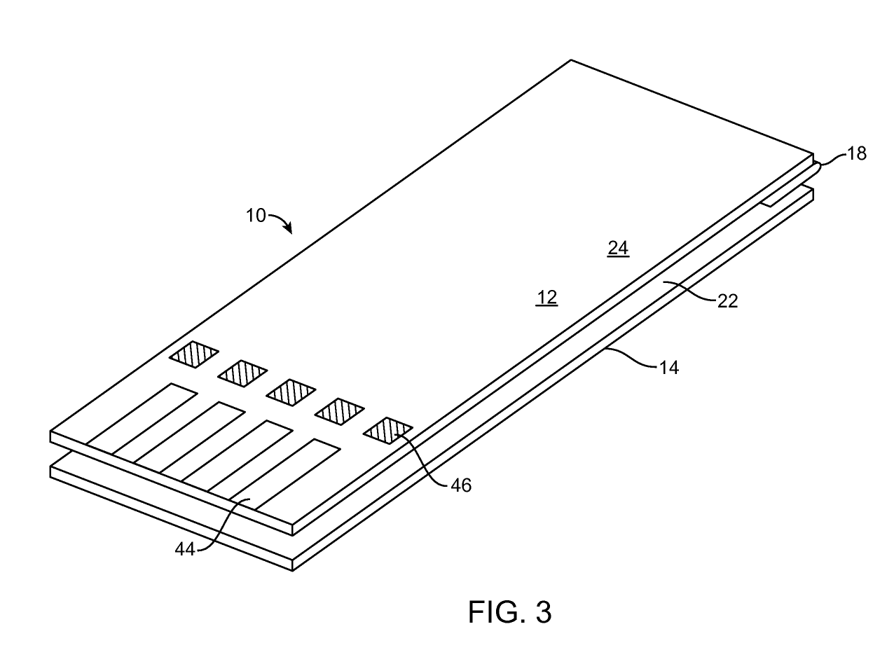

Electronic components 16 may be in electrical communication with each other via electrical pathways on either or both sides of substrates 12 and 14, as well as, if desired, pathways in internal conductive layers (not shown) of substrates 12 and 14. Contacts 44 and 46 can be an electrical communication with components 16 using any or all of such conductive pathways. Components 16 on first substrate 12 and components 16 on second substrate 14 may be an electrical communication with each other via flexible film cable 18. Flexible film cable 18, sometimes known as flexible flat cable, or FFC, can be any type of electrical cable that is both flat and flexible. It can be considered a miniaturized form of ribbon cable and usually consists of a flat and flexible film base with multiple metallic conductors sandwiched between that base and a second flexible plastic film layer. As in the case of substrate 12 and 14, flexible film cable 18 can include multiple layers of conductors insulated between layers of flexible plastic film. Flexible film cable 18 can be connected to first substrate 12 and second substrate 14 using conventional flexible film cable connectors, pads for solder connection or as otherwise desired. Preferably, the connection of flexible film cable 18 to first substrate 12 and second substrate 14 is sufficiently robust to allow the connections and the cable 18 to withstand folding of first substrate 12 onto second substrate 14 to form a stacked version of package 10 as shown, for example, in FIG. 3.

The package 10 of the embodiment shown in FIGS. 1A and 1B has application as an external memory device, such as, for instance, a USB (Universal Serial Bus) drive. Mass memory device 36 may be a flash device, a COB (Computer On Board) device, or any other desired mass memory device. A controller 38 may be a conventional microprocessor or other controller for coordinating with host devices to which package 10 may be physically and electronically connected via contacts 44 and/or 46. Optical device 40 may be a light emitting diode or other device for purposes such as indicating to a user the state or current activity of package 10 as it operates in connection with the host device to which it is connected or otherwise. Optical device 40 may constitute or include, if desired, an LED or other display that is capable of communicating alphanumeric texts, graphics and/or other information to users.

Electronic components 16 can include any desired dies, chip on board devices, flash or other mass memory devices, integrated circuits, signal processors, semiconductor devices or substrates, and/or discrete components such as, for example, capacitors, resistors, transformers, signal processors, diodes, non-packaged devices, inductors, FETs, or other devices capable of being mounted to first substrate 12 or second substrate 14 in connection with embodiments of the invention to carry out any desired purpose or to provide functionality of whatever desired sort. Such devices can also include high-speed digital logic or other devices, such as dynamic random access memory, static random access memory, application specific integrated circuits, accelerometers, microphones, speakers, other transducers or electromechanical devices, solar cells, optical receivers or transmitters, radio frequency circuits or devices, chronology circuits, pressure transducers, or any other desired component, again to carry out any desired purpose or to provide functionality of whatever desired sort.

In the embodiment shown in FIGS. 1A and 1B, electronic components 16 act in combination to provide functionality in the form of a mass memory drive that accommodates either or both a Universal Serial Bus (USB) standard and/or an external serial advanced technology attachment (eSATA) standard. Such standards govern communications protocols, physical interface elements, information and format, and other requirements according to which data may be communicated serially, processed and/or stored in the embodiment shown in FIG. 1A and 1B. First contacts 44 comply with a USB standard, which can be or include one or more of multiple variants, including USB 1.0, 1.1, 2.0, and 3.0. Any desired USB pin and housing configurations may be used, including type A, mini A, mini B, type B, micro A and micro B, any of which may be used in embodiments according to the present invention. Second contacts 46 in the particular embodiment shown in FIGS. 1A and 1B conform to a SATA standard, preferably an eSATA standard, including, if desired, and for example, any of SATA revisions 1.0, 2.0, 3.0, 3.1, mSATA or other SATA standards. Contacts could also, if desired, accommodate or conform to other standards such as, for example, parallel advanced technology attachment, FireWire (IEEE1394) or ExpressCard standards. Package 10 shown in FIGS. 1A and 1B configured for functioning as an external mass memory drive also includes a controller 38, a mass memory device 36, such as a flash drive, an optical device 40 such as an LED and/or other components as can be seen in FIGS. 1A and 1B. The contacts 44 and 46 and mass memory device 36 on first substrate 12 are in electrical communication with controller 38, LED 40 and other components 16 on second substrate 14 via flexible film cable 18. As can also be seen, flexible film 18 in combination with the two substrates 12, 14, allows for four substrate surfaces (20, 22, 24, and 26) on which to place electric components 16. In the embodiment shown in FIGS. 1A and 1B, contacts 44 and 46 are located on first substrate second side 24 while the mass memory device 36 is located on first substrate first side 20. Contacts 44 and 46 communicate with flash memory device 36 and other electronic components 16 according to conventional electronic pathways, which may be traces on external surfaces 20, 22, 24, 26 of substrates 12, 14, or internal conductors or pathways formed in layers of such substrates that may be interconnected using vias or any other conventional technique as desired. Flexible film cable 18 electrically connects such conductors or pathways on the different substrates 12, 14. Such connection can thus be configured to provide, if desired, the same functionality as if all electronic components 16 were on a single substrate rather than first substrate 12 and second substrate 14.

Through holes 48 shown in FIGS. 1A and 1B can be provided in one or both first substrate 12 and second substrate 14 to allow another form of electrical connection of components 16 on, for example, second substrate first side 22 to second substrate second side 26. Through holes 48 may be placed, in any desired location on first substrate 12 and second substrate 14. Such through holes 48 provide a potential upgrade path if the manufacturer later decides to add, for example, additional memory to second substrate second side 26 or other electronic components 16 such as, for example, to accommodate a new standard or to provide additional functionality. Components 16 can be mounted to first substrate 12 or second substrate 14, as the case may be, using surface mount, solder mount, or other mounting techniques as desired.

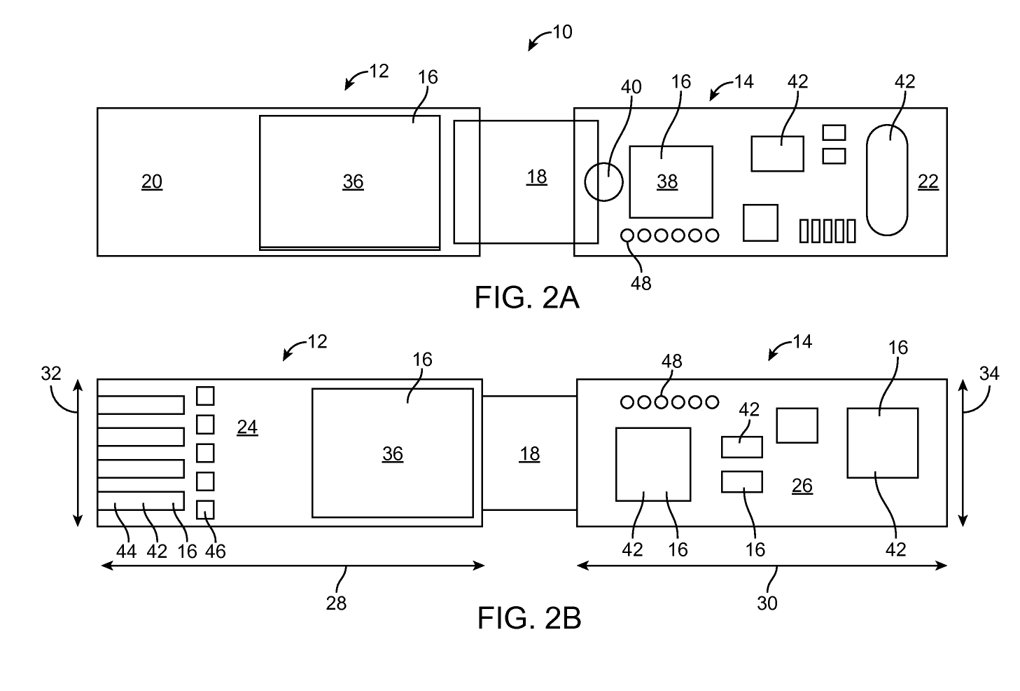

FIGS. 2A and 2B show a package 10 according to a second embodiment of the invention. In this embodiment, both sides 20, 24 of first substrate 12 and 22, 26 of second substrate 14 are populated with electronic component 16. Again, in this embodiment, package 10 is configured to provide external mass memory for a host device using a USB standard and an eSATA or other SATA standard end connectors. Again, in any embodiment where package 10 is intended to function as an external mass memory device, package 10 may provide contacts and a physical interface to accommodate one standard, two standards, or multiple external device connectivity and/or communications functionality. FIGS. 2A and 2B show the additional surface area on first substrate 12 and second substrate 14 that can be employed for mounting components 16, as compared to mounting such components on a single substrate that has the same length and width dimensions as first substrate 12 or second substrate 14. It is true that a single substrate with length and/or width dimensions greater than first substrate 12 or second substrate 14 could be used to provide such additional surface area. However, in that event, the resulting package 10 may prove too large in either or both length or width to accommodate market requirements or user expectations. For example, with respect to USB external memory devices, there is currently a consumer expectation that, unless decorative or ornamental aspects require, the device not be too long nor too wide, but rather of a conventional length and width. The inventor has found that there is less of such an expectation or requirement as to thickness of external mass memory devices, so that it is useful in the embodiments shown in FIGS. 1A, 1B, and 2A, 2B to provide additional board surface area in a way that will allow the external memory device to feature conventional length and width dimensions and thus conform more acceptably to market requirements and user expectations than if the substrate were longer and/or wider.

In the embodiment shown in FIGS. 2A and 2B, a controller 38, LED 40 and other components 16 are located on second substrate first side 22, while a flash memory device 36 is located on first substrate first side 20. On first substrate second side 24, another flash memory device 36 is provided, as are first contacts 44 that comply with a USB standard and second contacts 46 that comply with an eSATA standard. On second substrate second side 26, additional components 16 are mounted for additional functionality. Through holes 48 allow another form of electrical connection of components 16 on second substrate first side 22 and second substrate second side 26. Components 16 on various sides, 20, 22, 24, and 26 of first substrate 12 and second substrate 14 are in electrical communication with each other via pathways as described above in connection with FIGS. 1A and 1B.

FIG. 3 shows package 10 of FIGS. 1A, 1B when substrates 12, 14 have been folded to form a stacked spatial relationship so that first substrate first side 20 is adjacent second substrate first side 22. Adjacent for purposes of this spatial relationship means that first sides 20, 22 are facing each other and are spatially in the vicinity of each other, while allowing for the space occupied by electronic components 16 and any material that is used to bond substrates 12, 14 together, such as an epoxy or other polymeric material. Adjacent does not mean that first sides 20 and 22 are contacting each other.

When first substrate 12 and second substrate 14 are in this stacked relationship, flexible film cable 18 provides electrical communication between components 16 on first substrate 12 and on second substrate 14. In this particular embodiment, the substrates 12 and 14 provide some degree of physical protection to electronic components 16, if that is desired. First contacts 44 and second contacts 46 appear on an external surface of the package 10 and thus are disposed in a position to serve as electrical contacts, according to this particular embodiment, in compliance with a USB standard and an eSATA standard.

Package 10 as shown in FIG. 3 has essentially the same length dimension 50 and width dimension 52 as first substrate length dimension 28 and width dimension 33, and as second substrate length dimension 30 and width dimension 34. Thus, the stacked structure of package 10 provides twice as much substrate surface area as a single substrate, such as substrate 12 or 14 alone.

There is no requirement that first substrate 12 length dimension 28 and/or width dimension 32 be the same as second substrate 14 length dimension 30 and/or width dimension 34. It may be desired, for example, to have first substrate 12 be shorter or longer than second substrate 12. Similarly, first substrate 12 can be narrower or wider than second substrate 14. First substrate 12 and second substrate 14 may thus be longer, shorter, wider and/or narrower relative to each other to provide the desired package length dimension 50 and package width dimension 52 when first substrate 12 and second substrate 14 are in the stacked configuration as shown, for example, in FIG. 3.

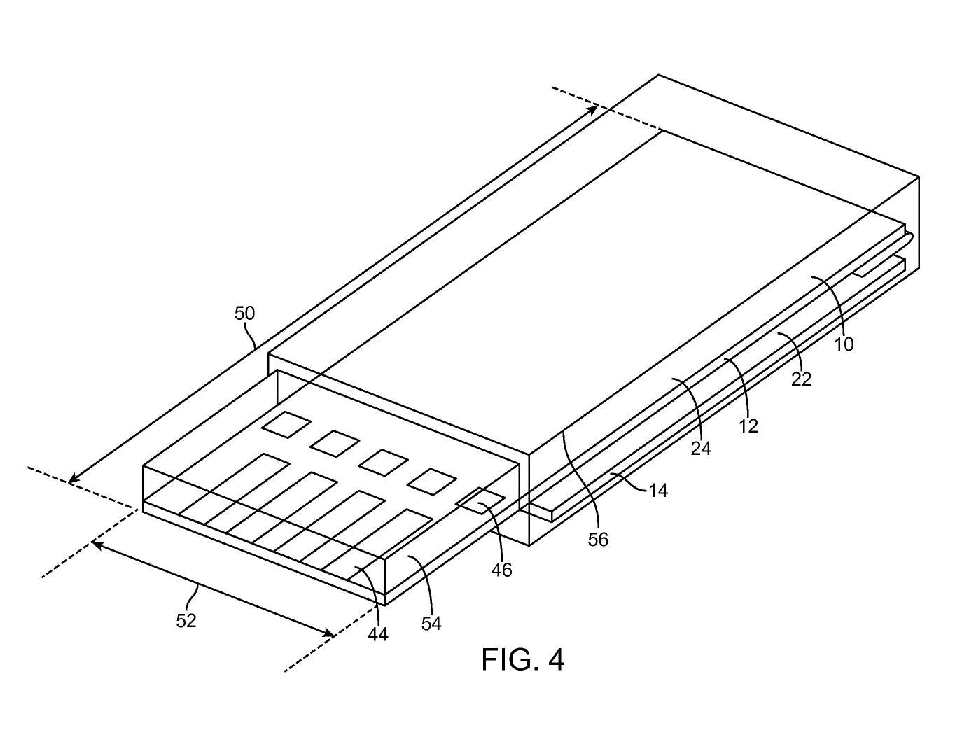

FIG. 4 shows a package 10 according to another embodiment of the invention. In this embodiment, first substrate 12 is longer than second substrate 14 so that circuit board of first substrate 12 can bear first contacts 44 and a second contacts 46 and a plug housing 54 that complies with USB and eSATA standards. Device housing 56 is provided to contain the package 10 to form a finished external memory device.

With respect to the embodiments shown in FIGS. 1A, 1B, 2A, 2B, 3 and 4 it bears emphasis that these are examples of packages 10 according to various embodiments of the invention, and there is no intention, nor should anything stated or implied in this document be construed to suggest, that package 10 and the description above is limited to external memory or storage devices, or such devices that comply with particular standards. Rather, structures and techniques according to various embodiments of the invention can be used when there is a desire to provide greater substrate surface for accommodating electronic components, while, at the same time, accommodating desired length, width, or other form factor considerations for the finished device. Stacked configurations shown by way of example in FIGS. 3 and 4 can have applications as external devices, but they can also be used internally in devices such as computers, mobile telephony devices, avionics equipment, automotive electronics, or any other situations where size matters.

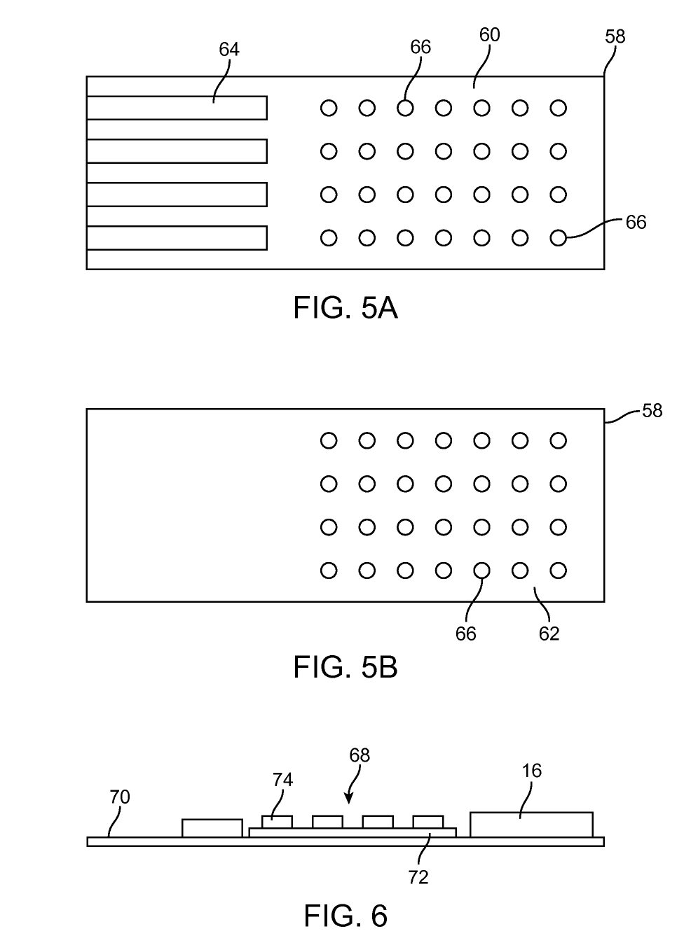

FIGS. 5A and 5B show a substrate 12 according to another embodiment of the invention. In this embodiment, substrate 58 can be for use as a substrate 12 or 14 as shown, for example, in FIG. 1 or 2, and thus in a stacked structure as shown in FIG. 3 or 4. Substrate 58 includes a first side 60 and a second side 62. Contacts 64 can be provided on a first side 60. Contacts 64 need not be provided; if desired, they can be provided on second side 62 instead of first side 60. Components 16 may be provided on one or both sides 60, 62 of substrate 58 and connected electrically using any of the techniques and pathways described above, in addition to using through holes 66. Through holes 66 thus provide potential of interconnectivity of components 16 located on substrate first side 60 and second side 62, in addition as desired, to the other traces, paths, layers, vias and other electrical pathways mentioned above. Through holes 66 thus provide an easy electrical connection mechanism or route for a pathway if additional components are mounted to substrate 58, such as, for example, at a time after original manufacture or design of the package 10 of which substrate 58 will form a part.

FIG. 6 shows a structure 68 according to another embodiment of the invention. Here, a first substrate 70 is provided, on which a second substrate 72 is mounted or disposed. Second substrate 72 may bear contacts 76 other electronic components 16 or other structures or devices. First substrate 70 may bear contacts 74 and components 16. First substrate 70 may be used as a first substrate 12 or second substrate 14, and in stacked substrate packages, as shown by way of example in any of FIGS. 1-4. FIG. 6 is provided to show that first substrate 12 and second substrate 14 may be provided and stacked according to various embodiments of the invention while at the same time themselves including additional substrates or layers of substrate, each substrate bearing or not bearing components 16 as desired.

In manufacture, electronic components 16 may be mounted on first substrate 12 and second substrate 14. The substrates 12, 14 and the components 16 thereon may be connected with flexible film cable 18. First substrate 12 and second substrate 14 may then be folded together so that they are stacked with first substrate first side 20 disposed adjacent to second substrate first side 22. As desired, physical housings such as, for example, plug housings 54 and/or device housings 56 may be added to provide finished devices for consumer use or other purposes. Alternatively, packages 10 containing substrates 12, 14 can be provided as components of other systems or devices without the need for housings such as housings 54 or 56 or contacts 44, 46. Instead of contacts such as first or second contacts 44 or 46, cable connectors, pads or other interconnection structures may be provided on either or first substrate 12 and second substrate 14 to allow interconnection to devices of which package 10 will form a part.

The foregoing has been provided for purposes of describing certain, nonlimiting, embodiments of the invention. Nothing in this disclosure should be interpreted as precluding variations, modifications, additions to or deletions from the particular embodiments described or illustrated herein that are within the scope or spirit of the invention.

What is claimed is:

1. Electronic component package, comprising:
A first substrate comprising a first substrate first side, a first substrate second side, a first substrate length dimension and a first substrate width dimension;
A plurality of first substrate electronic components mounted on the first substrate first side, at least some of the first substrate electronic components electrically connected to each other;
A second substrate comprising a second substrate first side, a second substrate second side, a second substrate length dimension and a second substrate width dimension;
A plurality of second substrate electronic components mounted on the second substrate first side, at least some of the second substrate electronic components electrically connected to each other;
A flexible film cable electrically connecting at least some of the first substrate electronic components to at least some of the second substrate electronic components;
The first substrate and the second substrates disposed in a stacked relationship where the first substrate first side is disposed adjacent to the second substrate first side.

2. A package according to claim 1 wherein the package comprises a package length dimension that does not exceed the greater of the first substrate length dimension and the second substrate length dimension.

3. A package according to claim 1 wherein the package comprises a width dimension that does not exceed the greater of the first substrate width dimension and the second substrate width dimension.

4. A package according to claim 1 wherein the first substrate and the second substrate are bound to each other with polymeric material.

5. A package according to claim 1 wherein the first substrate second side and the second substrate second side comprise conductive pathways that connect electronic components to each other.

6. A package according to claim 1 wherein the first substrate comprises a plurality of through holes, the through holes configured to permit electrical connection of electronic components on the first substrate first side to electronic components on the first substrate second side.

7. A package according to claim 1 wherein the second substrate comprises a plurality of through holes, the through holes configured to permit electrical connection of electronic components on the second substrate first side to electronic components on the second substrate second side.

8. A package according to claim 1 wherein at least one of the first substrate and the second substrate includes a plurality of contacts configured to permit connection of at least some electronic components mounted on at least one of the first substrate and the second substrate to an external device.

9. A package according to claim 8 wherein the electronic components comprise a mass memory device, a controller and at least one optical device, and the contacts are configured to comply with a universal serial bus standard and surrounded by a plug housing configured to comply with the universal serial bus standard.

10. A package according to claim 8 wherein at least one of the first substrate and the second substrate includes a first plurality of contacts configured to comply with a first interconnection standard and a second plurality of contacts configured to comply with a second interconnection standard.

11. A package according to claim 1 wherein at least some of the electronic components are surface mounted to at least one of the first substrate and the second substrate.

12. A package according to claim 1 further comprising a plurality of electronic components mounted to the first substrate second side.

13. A package according to claim 1 further comprising a plurality of electronic components mounted to the second substrate second side.

14. A package according to claim 1 wherein at least one of the first substrate and the second substrate comprises a plurality of conductive layers, each conductive layer separated from another conductive layer by an insulative layer, and a plurality of vias in at least one insulative layer, the vias permitting connection of conductive pathways in a conductive layer to conductive pathways in another conductive layer.

15. A package according to claim 1 wherein the flexible film cable electrically connects at least some of the first substrate electronic components to at least some of the second substrate electronic components using cable connectors.

16. A package according to claim 1 wherein the flexible film cable electrically connects at least some of the first substrate electronic components to at least some of the second substrate electronic components using solder connections.

17. Electronic component package, comprising:
A first substrate comprising a first substrate first side, a first substrate second side, a first substrate length dimension and a first substrate width dimension;
A plurality of first substrate electronic components mounted on the first substrate first side, at least some of the first substrate electronic components electrically connected to each other;
A second substrate comprising a second substrate first side, a second substrate second side, a second substrate length dimension and a second substrate width dimension;
A plurality of second substrate electronic components mounted on the second substrate first side, at least some of the second substrate electronic components electrically connected to each other;
Electronic components on at least one of the first substrate and the second substrate comprising a controller;
Electronic components on at least one of the first substrate and the second substrate comprising a mass memory device;
At least one of the first substrate and the second substrate comprising a first plurality of contacts configured to comply with a first interconnection standard;
A housing connected to at least one of the substrates, the housing configured to surround the first plurality of contacts, and to comply with the first interconnection standard;
A flexible film cable electrically connecting at least some of the first substrate electronic components to at least some of the second substrate electronic components;
The first substrate and the second substrate disposed in a stacked relationship wherein the first substrate first side is disposed adjacent to the second substrate first side;
Wherein the package comprises a package length dimension that does not exceed the greater of the first substrate length dimension and the second substrate length dimension and wherein the package comprises a width dimension that does not exceed the greater of the first substrate width dimension and the second substrate width dimension.

18. A package according to claim 17 wherein the first plurality of contacts is configured to comply with a universal serial bus standard.

19. A package according to claim 17 wherein the second substrate further comprises a second plurality of contacts configured to comply with a second interconnection standard and a housing configured to surround the first plurality of contacts and the second plurality of contacts, and to comply with the first interconnection standard and the second interconnection standard.

20. A package according to claim 19 wherein the second plurality of contacts and the housing are configured to comply with a serial advanced technology advancement standard.

21. A package according to claim 17 further comprising an optical device.

22. Electronic component package, comprising:
A first substrate comprising a first substrate first side, a first substrate second side, a first substrate length dimension and a first substrate width dimension;
A plurality of first substrate electronic components mounted on the first substrate first side, at least some of the first substrate electronic components electrically connected to each other;
A second substrate comprising a second substrate first side, a second substrate second side, a second substrate length dimension and a second substrate width dimension;
A plurality of second substrate electronic components mounted on the second substrate first side, at least some of the second substrate electronic components electrically connected to each other;
Electronic components on at least one of the first substrate and the second substrate comprising a controller;
Electronic components on at least one of the first substrate and the second substrate comprising a mass memory device;
At least one of the first substrate and the second substrate comprising a first plurality of contacts configured to comply with a universal serial bus standard and a second plurality of contacts configured to comply with a second interconnection standard;
A housing connected to at least one of the substrates, the housing configured to surround the first plurality of contacts and the second plurality of contacts, and to comply with the universal serial bus standard and the second interconnection standard;
A flexible film cable electrically connecting at least some of the first substrate electronic components to at least some of the second substrate electronic components;
The first substrate and the second substrate disposed in a stacked relationship wherein the first substrate first side is disposed adjacent to the second substrate first side;
Wherein the package comprises a package length dimension that does not exceed the greater of the first substrate length dimension and the second substrate length dimension and wherein the package comprises a width dimension that does not exceed the greater of the first substrate width dimension and the second substrate width dimension.
